(19) United States
(12) Patent Application Publication
(10) Pub. No.: US 2014/0283734 A1
(43) Pub. Date: Sep. 25, 2014

(54) MICROWAVE HEAT TREATMENT METHOD

(71) Applicant: TOKYO ELECTRON LIMITED, Tokyo (JP)

(72) Inventors: Taichi MONDEN, Nirasaki City (JP); Junichi KITAGAWA, Nirasaki City (JP); Seokhyoung HONG, Nirasaki City (JP); Yoshiro KABE, Nirasaki City (JP)

(73) Assignee: TOKYO ELECTRON LIMITED, Tokyo (JP)

(21) Appl. No.: 14/223,547

(22) Filed: Mar. 24, 2014

(30) Foreign Application Priority Data
Mar. 25, 2013 (JP) 2013-062053

(51) Int. Cl. C30B 1/02; C30B 30/00

(52) U.S. Cl. CPC C30B 1/023; C30B 30/00
USPC 117/8

(57) ABSTRACT

The present disclosure relates to a heat treatment method of performing a single crystallization of amorphous silicon formed on a substrate to be processed by irradiating the substrate with a microwave. The heat treatment method includes: irradiating the substrate with a microwave to increase a temperature of the substrate to a first temperature such that the amorphous silicon formed on the substrate becomes a single crystal at an interface between the substrate and the amorphous silicon and a nucleation does not occur in a region except the interface; irradiating the substrate with a microwave to heat the substrate at the first temperature for a predetermined period; irradiating the substrate with the microwave to increase the first temperature to a second temperature, which is higher than the first temperature; and irradiating the substrate with the microwave to heat the substrate at the second temperature.

### CROSS-REFERENCE TO RELATED APPLICATION

This application claims the benefit of Japanese Patent Application No. 2013-062053, filed on Mar. 25, 2013, in the Japan Patent Office, the disclosure of which is incorporated herein in its entirety by reference.

### TECHNICAL FIELD

The present disclosure relates to a microwave heat treatment method in which a substrate to be processed is heated by introducing microwave into a processing container.

### BACKGROUND

In manufacturing a semiconductor device, for example, impurity ions are implanted into a silicon substrate, and amorphous silicon formed on the surface of the substrate that is caused by a crystal defect due to ion implantation is recovered and crystallized, and a diffusion layer is formed on the surface layer of the silicon substrate. As a heat treatment method for the above process, a RTA (Rapid Thermal Annealing) method is commonly used, in which a lamp heater is used to irradiate light with a pulse width of, for example, an order of milliseconds. The temperature of the substrate that is heated by using the RTA method reaches about 900 Celsius degrees.

Recently, however, along with a miniaturization of a semiconductor device, there is a demand for forming a shallow diffusion layer by reducing a depth of the diffusion layer in the direction of the width of the substrate. In order to obtain a shallow diffusion layer, the temperature for heat treatment needs to be reduced thereby restraining impurities from being spread. However, this may result in an insufficient activation of impurities that causes the electrical resistance of a diffusion layer to increase.

To resolve the above problem, recently, a microwave heating method has been suggested. In case of using a microwave heating, microwave acts directly on impurity ions, thereby activating them at a lower temperature than that of the RTA method and thus restraining a diffusion layer from being expanded. Thus, a shallow diffusion layer can be formed.

The related art (JP2011-077408A) discloses a heat treatment method that can be used to form a very shallow diffusion layer as required. According to this method, ions are implanted into a silicon substrate, and the substrate is heated by irradiating microwave to the silicon substrate. The substrate is then further heated by irradiating light with a pulse width from 0.1 to 100 milliseconds generated by a lamp heater. Further, while microwave is being irradiated, the temperature of the substrate temperature is maintained to be below 600 Celsius degrees thereby restraining the expansion of a diffusion layer, so as to form a very shallow diffusion layer on the surface of the substrate.

Further, as a defect is recovered by the heat treatment, amorphous silicon that is caused to form by the ion implantation is gradually re-crystallized along a crystal orientation of the substrate, which results in a formation of a single silicon crystal. However, because the temperature of the substrate being thermal-processed using the RTA method reaches about 900 Celsius degrees, a nucleation occurs on the opposite side of the interface between the substrate and the amorphous silicon, i.e. amorphous silicon at the surface layer of the substrate. As a result, the amorphous silicon is crystallized to become polysilicon having a crystal orientation different from that of the substrate. This may prevent a fine single crystal from being formed in a diffusion layer. For instance, there is a problem of increasing the contact resistance of a source and a drain, in case a crystallized diffusion layer is used for a floating gate of a NAND circuit, etc.

To restrain such polysilicon generation on the surface layer of the substrate, a heat treatment method considered in the related art for heating the substrate at a temperature around 600 Celsius degrees is also considered. However, in that case, it takes much time to crystallize the amorphous silicon and such crystallization is also insufficient, and thus amorphous silicon is remained on the surface layer of the substrate. For that reason, there is a need for a technique of forming a fine single crystal by growing the amorphous silicon as a crystal along a crystal orientation of the substrate.

### SUMMARY

Some embodiments of the present disclosure provide a microwave heat treatment method to form a fine single crystal on a substrate to be processed, by introducing microwave into a processing container for a heat treatment for heating the substrate.

According to one embodiment of the present disclosure, there is provided a heat treatment method of performing a single crystallization of amorphous silicon formed on a substrate to be processed by irradiating the substrate with a microwave. The method includes: irradiating the substrate with a microwave to increase a temperature of the substrate to a first temperature such that the amorphous silicon formed on the substrate becomes a single crystal at the interface between the substrate and the amorphous silicon and a nucleation does not occur in a region except the interface; irradiating the substrate with the microwave to heat the substrate at the first temperature for a predetermined period; irradiating the substrate with the microwave to increase the first temperature to a second temperature, which is higher than the first temperature; and irradiating the substrate with the microwave to heat the substrate at the second temperature.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional view schematically showing a microwave heat treatment apparatus according to the present embodiment.

FIG. 2 is an explanatory view schematically showing a configuration of a microwave unit.

FIG. 3 is an explanatory view schematically showing a configuration of a power supply part.

FIG. 4 is a bottom view showing the bottom surface of a ceiling plate of a processing container.

FIG. 5 is an explanatory view showing the shape of an opening of a ceiling plate.

FIG. 6 is an explanatory view schematically showing the status of a section near the surface of a wafer.

FIG. 7 is an explanatory view showing the profile of a heat treatment.

FIG. 8 is an explanatory view showing a correlation between the thickness of amorphous silicon and a temperature for crystallization.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In the present specification and drawings, it is omitted to give a repetitive explanation of the components with same reference numerals because those components have a substantially identical function or configuration.

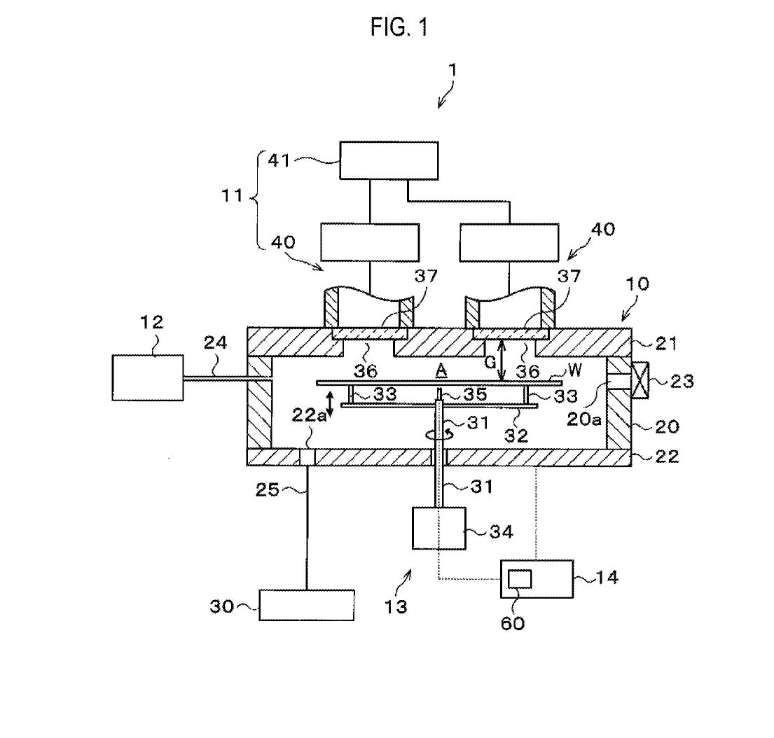

FIG. 1 is a longitudinal sectional view schematically showing a microwave heat treatment apparatus 1 according to the present embodiment. Further, in the present embodiment, a heat treatment of, for example, a semiconductor wafer (hereinafter, referred to as a “wafer”) W by performing a microwave heat treatment apparatus 1 is explained as an exemplary case. Furthermore, according to the present embodiment, a wafer W, for example, is a silicon substrate, and due to implantation of ion impurities, a layer of amorphous silicon accompanying a crystal defect may be formed on the surface of the wafer substrate.

As shown in FIG. 1, a microwave heat treatment apparatus 1 includes a processing container 10 configured to accommodate a wafer W used for the substrate to be processed; a microwave introducing mechanism 11 configured to introduce microwave into the processing container 10; a gas supply mechanism 12 configured to supply a predetermined amount of gas into the processing container 10; a support mechanism 13 configured to support the wafer W in the processing container 10; and a control part 14 configured to control each unit of the microwave heat treatment apparatus 1. The processing container 10 is formed by a metal, for example, such as aluminum, stainless steel, etc.

Overall, the processing container 10 is, for example, a substantially rectangular cylinder-shaped container, and includes, when seen from a plan view, a sidewall 20 having, for example, a square-tube shape, a ceiling plate 21 covering the top of the sidewall 20 and having a substantially square shape, and a bottom plate 22 covering the bottom of the sidewall 20 and having a substantially square shape. In a region surrounded by the sidewall 20, the ceiling plate 21, and the bottom plate 22, a processing space A of the processing container 10 is formed. In addition, the surfaces of the sidewall 20, the ceiling plate 21 and the bottom plate 22 at the side of the processing space A are processed with a mirror surface finishing, such that these surfaces function as a reflective surface for reflecting the microwave. Thus, it is possible to increase the final temperature of a heat treatment of the wafer W, compared to the case without the mirror surface finishing.

A carrying in/out hole 20a configured to import/export the wafer W is formed at the sidewall 20 of the processing container 10. At the carrying in/out hole 20a, a gate valve 23 is installed such that the gate valve 23 can be opened and closed by a driving unit (not shown). Between the gate valve 23 and the sidewall 20, a seal member (not shown) is installed to block a leakage of the microwave. Also, the gas supply mechanism 12 is connected, through a supply pipe 24, to the sidewall 20 of the processing container 10. Furthermore, a gas, for example, such as nitrogen gas, argon gas, helium gas, neon gas, and hydrogen gas is provided, for example, as a processing gas or a cooling gas from the gas supply mechanism 12.

On the bottom plate 22 of the processing container 10, an exhaust 22a is formed, and the exhaust 22a is connected to an exhaust mechanism 30 such as, for example, a vacuum pump, etc., through an exhaust pipe 25. Also, the support mechanism 13 is installed on the bottom plate 22.

The support mechanism 13 includes a shaft 31 having a hollow-tube shape that passes through the center of the bottom plate 22 in upward and downward directions and is elongated to an outside of the processing container 10; an arm 32 installed near the top of the shaft 31 and elongated in a horizontal direction; and a support pin 33 installed on the top of the arm 32 to support the wafer W. A driving mechanism 34 configured to rotate and elevate the shaft 31 is connected to the bottom of the shaft 31. In the processing container 10, the position of the wafer W in a height direction is controlled by the driving mechanism 34 to move and elevate the support pin 33 supporting the wafer W. The driving mechanism 34 is placed, for example, outside the processing container 10. Furthermore, a space between the shaft 31 and the bottom plate 21 is air-tightly filled with a seal member (not shown).

In addition, a temperature measurement mechanism 35 is installed within the shaft 31 to measure the temperature of the wafer W. An emission thermometer, for example, is used as the temperature measurement mechanism 35. The temperature of the wafer W measured by the temperature measurement mechanism 35 is input to the control part 14, and used to control microwave heating of the wafer W.

At the ceiling plate 21 of the processing container 10, an opening 36 is formed to introduce the microwave into the processing container 10 as a microwave inlet port, and a transmission window 37 is installed to block the opening 36. A microwave introducing mechanism 11 is installed at an upper side of the opening 36, and includes a microwave unit 40 configured to generate the microwave and a power supply part 41 connected to the microwave unit 40. According to the present embodiment, for example, the number of the transmission windows 37 and the number of the microwave units 40 is four, respectively, and the number of the power supply part 41 is one.

The transmission window 37 is formed, for example, using dielectrics such as quartz, ceramics, etc. A space between the transmission window 37 and the ceiling plate 21 is air-tightly filled with a seal member (now shown). Further, a distance G from the bottom of the transmission window 37 to the wafer W heated in the processing container 10 is set, for example, from 25 mm to 50 mm, in terms of keeping the microwave from being directly irradiated to the wafer W. The detailed arrangement of the transmission window 37 will be later described.

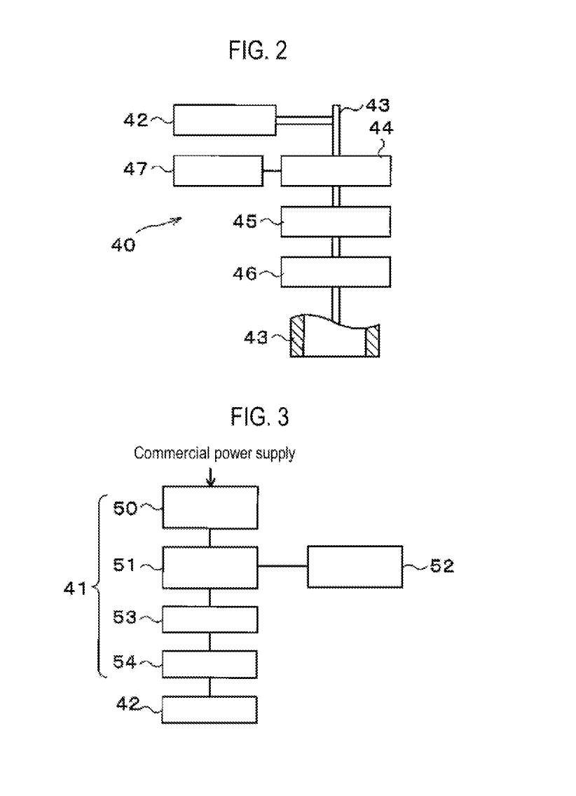

The microwave unit 40, for example as shown in FIG. 2, includes a magnetron 42 configured to generate microwave; a wave guide 43 configured to transmit the microwave; a circulator 44 installed between the wave guide 43 and the transmission window 37; a detector 45; a tuner 46; and a dummy load 47 connected to the circulator 44.

In order to apply a high voltage through the power supply part 41, the magnetron 42 includes a positive electrode and a negative electrode, which are not shown. The magnetron 42 may employ an oscillator that can oscillate a variety of frequencies of the microwave. Also, the frequency of the microwave generated by the magnetron 42 is chosen to be an optimal frequency for processing the wafer W that is used as a substrate to be processed. For instance, for a heat treatment, microwave having a frequency higher than 2.45 GHz may be used, and more specifically, microwave having a frequency of 5.8 GHz may be used.

The wave guide 43 has a rectangular cross-section, and is tube-shaped. Also, the wave guide 43 is elongated in an upward direction from the top surface of the ceiling plate 21 and the transmission window 37 of the processing container 10. The magnetron 42 is connected to near the top of the wave guide 43. Being generated from the magnetron 42, the microwave is transmitted into the processing space A of the processing container 10 through the wave guide 43 and the transmission window 37.

From the top of the wave guide 43 to its bottom, the circulator 44, the detector 45, and the tuner 46 are installed in this order. The circulator 44 and the dummy load 47 function as an isolator sorting a reflected wave of microwave introduced into the processing container 10. In other words, the reflected wave from the processing container 10 is transmitted to the dummy load 47 by the circulator 44, and then the dummy load 47 converts the reflected wave transmitted by the circulator 44 into heat.

The detector 45 detects the reflected wave at the wave guide 43 from the processing container 10. For instance, the detector 45 includes an impedance monitor, more specifically, a standing wave monitor configured to detect an electric field of a standing wave at the wave guide 43. Furthermore, the detector 45 may include, for example, a directional coupler configured to detect a traveling wave and a reflected wave.

The tuner 46 controls impedance such that the impedance between the magnetron 42 and the processing container 10 is matched by the tuner 46. An impedance matching by the tuner 46 is performed based on the detection result of the reflected wave from the detector 45.

The power supply part 41 applies a high voltage to the magnetron 42 to generate the microwave. The power supply part 41, for example as shown in FIG. 3, includes a AC-DC conversion circuit 50 connected to a commercial power supply; a switching circuit 51 connected to the AC-DC conversion circuit 50; a switching controller 52 configured to control the operation of the switching circuit 51; a step-up transformer 53 connected to the switching circuit 51; and a rectifier circuit 54 connected to the step-up transformer 53. The step-up transformer 53 and the magnetron 42 are connected with each other through the rectifier circuit 54.

In the AC-DC conversion circuit 50, for example, a three-phase AC voltage of 200V from a commercial power supply is rectified and converted to a DC voltage. The switching circuit 51 is a circuit configured to control an ON/OFF of the DC voltage converted by the AC-DC conversion circuit 50. In the switching circuit 51, a pulse-shaped voltage is generated through Pulse Width Modulation (PWM) or Pulse Amplitude Modulation (PAM) by the switching controller 52. A pulse-shaped voltage generated from the switching circuit 51 is boosted by the step-up transformer 53. The boosted pulse-shaped voltage is then rectified by the rectifier circuit 54 and supplied to the magnetron 42.

The following explains the placement of the opening 36 formed on a ceiling plate 21, where the opening 36 functions as the microwave inlet port. FIG. 4 shows a view from the bottom of the ceiling plate 21. Referring to FIG. 4, the mark “O” indicates the center of a wafer and the ceiling plate 21. Also, the mark “M” indicates a line connecting the middle points of opposite sides among four boundary sides between the ceiling plate 21 and the sidewall 20. Furthermore, the center of the wafer W and that of the ceiling plate 21 do not necessarily coincide with each other.

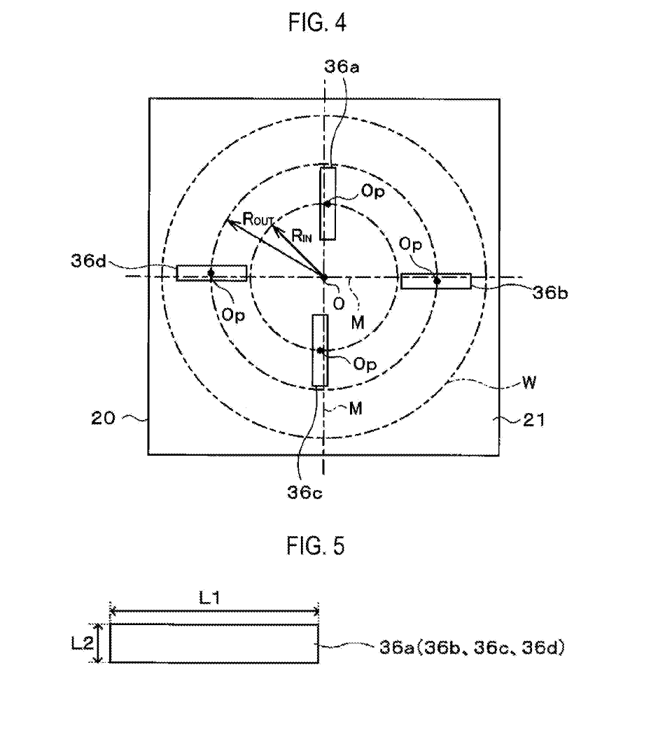

As shown in FIG. 4, for example, four openings 36a, 36b, 36c and 36d formed on the ceiling plate 21 are placed approximately along the center line M in an approximately cross-shaped arrangement. As shown in FIGS. 4 and 5, each opening 36a, 36b, 36c and 36d is formed in a rectangular shape. The ratio of the length of a longer side L1 to that of a shorter side L2 ranges, for example, from 2 to 100, and more specifically ranges from 5 to 20. The ratio is determined to be greater than or equal to 2 to strengthen the directivity of the microwave in a direction perpendicular to the longer side of the openings 36a, 36b, 36c and 36d, where the microwave is irradiated into the processing container 10 from each opening 36a, 36b, 36c and 36d. When the ratio is below 2, the directivity of the microwave in a direction perpendicular to the openings 36a, 36b, 36c and 36d is also strengthened. Accordingly, if the distance G between the transmission window 37 and the wafer W is short, the microwave is directly propagated only to a part of the wafer W, and thus, the wafer W is locally heated. On the other hand, if the ratio is over 20, the directivity of the microwave in a direction perpendicular to the openings 36a, 36b, 36c and 36d or parallel to the longer side of the openings 36a, 36b, 36c and 36d will be excessively decreased. Thus, the heating efficiency of the wafer W will be reduced.

In addition, the length of the longer side L1 of each opening 36a, 36b, 36c and 36d may be set to be L1=n×λg/2, where n is a positive integer and λg is a wavelength within the wave guide 43. Furthermore, the size of each opening 36a, 36b, 36c and 36d or the ratio of the lengths L1 and L2 may be different with each other for each opening 36a, 36b, 36c and 36d. However, the size of each opening 36a, 36b, 36c and 36d may be set to be identical, or the lengths L1 and L2 may be set to be identical if a uniform heat treatment is considered through a uniform irradiation of the microwave to the wafer W.

Also, in the present embodiment, to maintain a uniform distribution of the electric field near the top of the wafer W, the center of each opening 36a, 36b, 36c and 36d, for instance as shown in FIG. 4, is overlapped with one of two concentric circles, where these circles, for example, have a smaller diameter than the wafer W and are centered on a center O of the wafer W. In this case, centers Op of the openings 36a, 36b, 36c and 36d are not placed along the identical circumference. According to the present embodiment, for instance as shown in FIG. 4, two openings 36a and 36c, for example, are placed on a circumference having a radius R_{IN}, while openings 36b and 36d are placed on a circumference having a radius R_{OUT} that is greater than R_{IN}.

Also, as shown in FIG. 4, each opening 36a, 36b, 36c and 36d is placed in such a manner that their longer and shorter sides are parallel to the internal side area of the sidewall 20, respectively. In FIG. 4, the longer sides of two openings 36a and 36c are parallel to the sidewall 20 in a forward and a reverse direction of the X-direction. In addition, the longer sides of the other two openings 36b and 36d are parallel to the sidewall 20 in a forward and a reverse direction of the Y-direction.

Further, each opening 36a, 36b, 36c and 36d is placed in a position that does not interfere with the other openings, if it is translated in parallel in a direction perpendicular to each of its longer side. For instance, the opening 36a shown in FIG. 4 does not interfere with the openings 36b and 36d, even if the opening 36a is translated in a direction perpendicular to its longer side, i.e. in the X-direction, and thus, it does not interfere with the opening 36c. Under this condition, each opening 36a, 36b, 36c and 36d is placed in an approximately cross-shaped arrangement. Thus, microwave and its reflected wave irradiated with a strong directivity in a direction perpendicular to a longer side of each opening 36a, 36b, 36c and 36d are restrained to enter the other openings 36a, 36b, 36c and 36d. So, the loss of the microwave and its reflected wave due to the irradiation through each opening 36a, 36b, 36c and 36d is restrained, and an efficient microwave heat treatment by the microwave can be performed.

In addition, according to the present embodiment, among the openings 36a, 36b, 36c and 36d placed substantially in a cross-shaped arrangement, two openings not neighboring with each other are placed in such a manner that each of their centers Op is not placed along the same line that is parallel with the center line M. For instance, the centers Op of the openings 36a and 36c, with their longer sides aligned in the same direction, are placed in locations with predetermined distances from the center axis M in different directions, respectively. By placing the openings 36a and 36c as mentioned above, the irradiated microwave enters in between the openings 36a and 36c, in a direction perpendicular to a shorter side of each opening, respectively. Accordingly, it is possible to restrict the occurrence of power loss. Also, for example, if the centers Op of the openings 36a and 36c are not placed in the same line shape, one of the centers Op of the openings can be overlapped with the center line M. The arrangement of each opening 36a, 36b, 36c and 36d is not limited to the present embodiment, but any suitable arrangement satisfying the above-mentioned relationship may be chosen.

The control part 14 includes a memory part 60. From the recipe recorded on the memory part 60, the control part 14 controls each mechanism of the microwave heat treatment apparatus 1. Also, the command of the control part 14 is executed by a special-purpose control device or a CPU (not shown) that executes a program. The recipe with a selected process condition is prerecorded in a ROM or a non-volatile memory (not shown). From these memories, a CPU decodes the condition of the recipe and executes the recipe.

According to the present embodiment, the microwave heat treatment apparatus 1 is configured as mentioned above. In the following, the heat treatment of the wafer W by the microwave heat treatment apparatus 1 is explained in more detail.

For performing heat treatment of the wafer W, the gate valve 23 is operated to be opened, and the wafer W is carried into the processing container 10 by a conveying mechanism (not shown). The carried wafer W is loaded on the support pin 33. Then, the gate valve 23 is operated to be closed, and a lower pressure atmosphere is obtained by exhausting a processing container 10 by an exhaust apparatus 130. Then, a predetermined amount of flux of processing gas and cooling gas is supplied into the processing container 10 through the gas supply mechanism 12.

Then, the voltage of the magnetron 42 is supplied from a power supply part 41. Also, the microwave generated from the magnetron 42 is irradiated through the wave guide 43 and then is introduced into the processing space A inside the processing container 10 through the transmission window 37. At this time, the shaft 31 is rotated by the driving mechanism 34, and the wafer W loaded on the support pin 33 is also rotated at a predetermined speed.

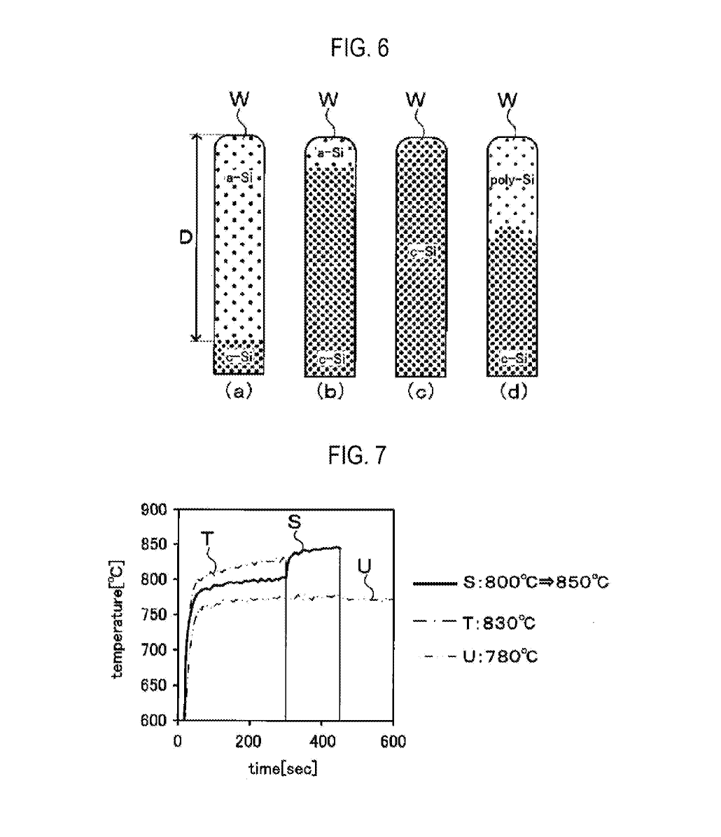

The microwave introduced into the processing container 10 is irradiated to the surface of the wafer W, which is processed to be heated. At this time, the output of the irradiated microwave is adjusted such that the wafer W is heated to a first temperature. The first temperature is lower than a heat treatment temperature that can be obtained using the RTA method. More specifically, regarding amorphous silicon on the wafer W, the first temperature is set in such a manner that a nucleation of a single silicon crystal does not occur in the region except the interface between the wafer W and the amorphous silicon. In case of using a silicon substrate as the wafer W and, for example, if the implanted ion is arsenic, phosphorus or boron, the first temperature may be about 600 to 800 Celsius degrees although the first temperature also depends on the shape of the amorphous silicon or ion concentration. Also, according to the present embodiment, the first temperature, for example, is set to 800 Celsius degrees. After ion implantation, for instance as shown in item (a) of FIG. 6, the amorphous silicon has a predetermined thickness D on the top of the wafer W, which is a single silicon crystal. However, as the amorphous silicon is heated at the first temperature, the amorphous silicon gradually becomes a single crystal again. Thus, as shown in item (b) of FIG. 6, the thickness of the amorphous silicon is becoming smaller. At this time, the wafer W is heated at the first temperature which is below a heat treatment temperature that can be obtained by using the RTA method. For that reason, a nucleus of a silicon crystal is not generated within the amorphous silicon except its interface with a single silicon crystal. Accordingly, it is possible to restrain the amorphous silicon from becoming polysilicon.

After the wafer W is heated for a predetermined time at the first temperature, the wafer W is heated to a second temperature by increasing the microwave output. At this time, the microwave output is increased in a stepwise manner. For example, as shown in a line S of FIG. 7, the temperature of the wafer W reaches the second temperature in a short period. The line S of FIG. 7 shows the recipe of a heat treatment of the wafer W according to the present embodiment. In addition, in case of heating the wafer W, the wafer W may be heated by increasing the microwave output as well as raising the shaft 31 by the driving mechanism 34. As a result, the reflection of the microwave irradiated to the wafer W is restrained, and the speed of raising temperature can be increased. Further, the period prior to changing from the first temperature to the second temperature, i.e. the heating time with the first temperature, refers to a period of time during which the remaining thickness of the amorphous silicon on the wafer W is reduced to, for example, 10 nm to 20 nm. In the present embodiment, the heating time is about 300 seconds. The research by the present inventors indicates that the speed of crystallization is extremely reduced even when the amorphous silicon is heated at the first temperature, under the condition that the thickness of the amorphous silicon is about 10nm to 20 nm. In order to expedite the crystallization, a heat treatment temperature needs to be higher than the first temperature. Accordingly, in the present embodiment, the wafer W is heated until its temperature reaches the second temperature when the remaining thickness of the amorphous silicon is about 10 nm to 20 nm, to re-crystalize all amorphous silicon quickly. In this case, the second temperature is about 700 to 1000 Celsius degrees. In the present embodiment, the second temperature is, for example, 850 Celsius degrees.

The amorphous silicon on the wafer W is re-crystallized by being heated at the second temperature. As shown in item (c) of FIG. 6, all amorphous silicon remaining on the surface of the wafer W is crystallized along the same crystal direction as the crystal direction of the wafer W. The heating time of the amorphous silicon at the second temperature is, for example, 150 seconds.

After a heat treatment at the second temperature is completed, the power supply part 41 stops supplying the voltage to the magnetron 42. Also, the introduction of the microwave into the processing container 10 is stopped. At the same time, the driving mechanism 34 is stopped, so that the rotation of the wafer W is stopped. Also, the supply of processing gas and cooling gas from the gas supply mechanism 12 is stopped. Subsequently, the gate valve 23 is operated to be opened, and the wafer W is exported from the processing container 10 to the outside. In this manner, a series of heat treatment of the wafer W is completed.

According to the present embodiment above, the microwave is irradiated to the wafer W to perform the heat treatment for a predetermined period at the first temperature that is below the heat treatment temperature using the RTA method. Thus, in the surface layer portion of the amorphous silicon on the wafer W, a silicon crystal is restrained from growing with a different crystal direction from that of the wafer W. Also, in the interface between the substrate to be processed and the amorphous silicon, the amorphous silicon can become a single crystal along the crystal direction of the wafer W. Thereafter, the amorphous silicon is further heated at the elevated second temperature. Thus, the amorphous silicon does not remain on the surface of the wafer W, and all amorphous silicon can become a fine single crystal. In addition, the crystallization is performed at the first temperature and the second temperature that are lower than the heat treatment temperature using the RTA method. Thus, it is possible to form a shallow and quality diffusion layer on the wafer W.

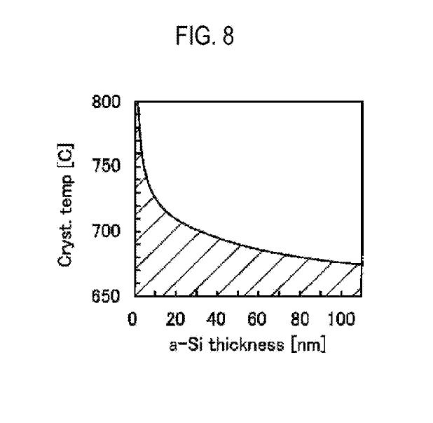

In addition, after the thickness of the amorphous silicon is reduced to 10 nm to 20 nm, the heat treatment temperature of the wafer W is increased from the first temperature to the second temperature. Accordingly, the remaining amorphous silicon can quickly be re-crystallized by the heat treatment performed at the second temperature. Thus, according to the present embodiment, the heat treatment efficiency of the wafer W can be improved. Also, the research of the present inventors confirms that, as shown in FIG. 8, a correlation exists between the thickness of the amorphous silicon at the top of the wafer W and the temperature at which the amorphous silicon is re-crystallized.

As shown in FIG. 8, as the thickness of the amorphous silicon is reduced, the temperature at which the amorphous silicon is crystallized is increased. As illustrated in FIG. 8, for instance if the thickness of the amorphous silicon is greater than 20 nm, the amorphous silicon can be crystallized at about 700 Celsius degrees. Meanwhile, if the thickness of the amorphous silicon is 10 nm to 20 nm, its crystallization requires the heat treatment temperature higher than 750 Celsius degrees. In addition, it is suitable to raise the heat treatment temperature of the wafer W from the first temperature to the second temperature, after the thickness of the amorphous silicon is reduced to 10 nm to 20 nm. On the other hand, if the thickness of the amorphous silicon is greater than 20 nm and the amorphous silicon is heated at the second temperature, for example, 150 Celsius degrees higher than a temperature for crystallization, its crystallization is progressed excessively. Thus, it can be inferred from FIG. 8 that the polysilicon is formed in the region except the interface between the wafer W and the amorphous silicon. Accordingly, as described in the above embodiment, it is suitable to continue heating at the first temperature until the thickness of the amorphous silicon is reduced to about 10 nm to 20 nm. Moreover, FIG. 8 shows a temperature for crystallization of amorphous silicon that is uniformly formed on the wafer W and not implanted with ions, such as arsenic or phosphorus, etc. Thus, the temperature for crystallization varies according to the type or concentration of ions implanted into the amorphous silicon and the shape of the amorphous silicon.

Also, as an example for comparison, if the wafer W is heated at 1050 Celsius degrees for ten seconds by using the RTA method, the polysilicon is formed near the surface layer of the wafer W, as shown in item (d) of FIG. 6. In addition, as an example for another comparison, if a heat treatment is performed at 600 Celsius degrees for 60 seconds by irradiating microwave to the wafer W, crystallization along the crystal direction of the wafer W is barely progressed from the state of item (a) of FIG. 6, and most of amorphous silicon is remained as well.

In the present embodiment, the microwave output is increased in a stepwise manner, when the heating temperature is increased from the first temperature to the second temperature, thereby heating the wafer W in a short time as shown in the line S of FIG. 7. However, the pattern of increasing temperature is not limited to the present embodiment. It is allowed to increase the temperature from the first temperature to the second temperature for a predetermined period, based on the data of FIG. 8. In other words, the output of the microwave irradiated to the wafer W could be increased by a predetermined value for a predetermined period. In this case, the output of microwave may be increased along a straight line or a curved line to obtain a temperature increment according to the curved line of FIG. 8.

In addition, for an example of another comparison, the present inventors verified the case where if the wafer W is heated by the irradiation of the microwave, a certain temperature is maintained for a fixed period as shown in a line T and a line U of FIG. 7. As shown in the line T of FIG. 7, in case the wafer W is heated at 830 Celsius degrees for 300 seconds, it is confirmed that the polysilicon is formed on a part of the surface layer of the wafer W. As mentioned above with respect to FIG. 8, this may be caused by a nucleation in the region excluding the interface between the amorphous silicon and the wafer W. In this case, the amorphous silicon is heated at a relatively high temperature of 830 Celsius degrees due to the large thickness of the amorphous silicon, even though it can be crystallized at around 700 Celsius degrees.

Furthermore, as illustrated by a line U of FIG. 7, the polysilicon is not formed when the wafer W is heated at 780 Celsius degrees for 600 seconds. However, it is confirmed that the amorphous silicon is remained on the surface layer of the wafer W because all amorphous silicon cannot be crystallized. This is because, if the thickness of amorphous silicon is reduced to, for instance, about 10 nm, the amorphous silicon will not be sufficiently crystallized at 780 Celsius degrees, or the speed of crystallization will be too slow to crystallize it within 600 seconds.

In the present embodiment, the wafer W includes a layer of the amorphous silicon accompanying a crystal defect of the surface layer of the wafer W, by implanting ion impurities into the silicon substrate. However, it is allowed to choose any other suitable materials for the wafer W or any other suitable types of ions to be implanted.

In addition, as shown in FIG. 8, the correlation between the thickness of the amorphous silicon and the temperature for crystallization varies, as explained above, according to the type or the concentration of ions doped into the wafer W, the shape of the amorphous silicon, or the material of the wafer W, etc. Thus, the first temperature and the second temperature may be determined to have suitable values depending on the material of the wafer W, the type of doping ions or their concentrations, or the shape of the amorphous silicon.

According to the present invention, a fine single crystal can be formed on the substrate, by heating the substrate to be processed through introducing microwave into a processing container.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A heat treatment method of performing a single crystallization of an amorphous silicon formed on a substrate to be processed by irradiating the substrate with a microwave, the method comprising:
irradiating the substrate with a microwave to increase a temperature of the substrate to a first temperature such that the amorphous silicon formed on the substrate becomes a single crystal at an interface between the substrate and the amorphous silicon and a nucleation does not occur in a region except the interface;
irradiating the substrate with a microwave to heat the substrate at the first temperature for a predetermined period;
irradiating the substrate with the microwave to increase the first temperature to a second temperature, which is higher than the first temperature; and
irradiating the substrate with the microwave to heat the substrate at the second temperature.

2. The method of claim 1, further comprising increasing an output of the microwave irradiated to the substrate in a stepwise manner while the first temperature is elevated to the second temperature.

3. The method of claim 1, further comprising increasing an output of the microwave irradiated to the substrate by a predetermined value for a predetermined period while the first temperature is elevated to the second temperature.

4. The method of claim 1, wherein the first temperature is 600 to 800 Celsius degrees and the second temperature is 700 to 1000 Celsius degrees.

5. The method of claim 1, wherein the substrate is a silicon substrate and the amorphous silicon on the substrate is formed by performing an ion implantation to dope at least one of arsenic, phosphorus and boron into the substrate.

6. The method of claim 1, wherein the predetermined period of heating at the first temperature is a period until a thickness of the amorphous silicon is reduced to 10 nm to 20 nm due to a heating of the amorphous silicon.
